(19) United States
(12) Patent Application Publication
(10) Pub. No.: US 2005/0007167 A1
(43) Pub. Date: Jan. 13, 2005

(54) PWM switching regulator control circuit

(76) Inventor: Yoshihisa Tange, Chiba-shi (JP)

Correspondence Address: ADAMS & WILKS, 31st Floor, 50 Broadway, New York, NY, 10004, US

(21) Appl. No.: 10/888,662

(22) Filed: Jul. 9, 2004

(30) Foreign Application Priority Data
Jul. 10, 2003 (JP) 2003-194737
Jun. 18, 2004 (JP) 2004-180699

(51) Int. Cl. H03K 3/017

(52) U.S. Cl. 327/172

(57) ABSTRACT

To provide a PWM switching regulator control circuit, which is small in the ripple voltage without a drop of the output voltage which, is attributable to a load at the time of a soft start. A PWM switching regulator control circuit is provided, in which an offset voltage that is lower than a reference voltage is inputted to an error amplifier at the time of a soft start, to thereby prevent an off-time from occurring in the PWM comparator output, prevent the output voltage that is attributable to the load from dropping, and make the ripple voltage small.

### BACKGROUND OF THE INVENTION

1. Field of the Invention

The present invention relates to a PWM switching regulator control circuit having a soft start function.

2. Description of the Related Art

In order to suppress a rash current at the time of turning on a power or an overshoot of an output voltage, some of PWM switching regulator control circuits provide a soft start function. The operation of the conventional soft start function will be described in order from a situation where no supply voltage is present at all with reference to FIGS. 2 and 3.

First, when a power is connected to the PWM switching regulator control circuit, an output voltage VOUT rises from 0 V, a current flows into a capacitor 207 from a constant current source 206, and a gate voltage of an n-channel MOS transistor 204 gradually rises. As a result, since a voltage VREF of a reference voltage 203 makes a voltage at a non-inversion input terminal of an error amplifier 208 slowly rise, a rash current and an overshoot of the output voltage VOUT can be suppressed. This function is called “soft start function”.

The error amplifier 208 outputs a difference between a feedback voltage Va that has derived from dividing the output VOUT through divided resistors 201 and 202 and a voltage VREF that is outputted from the reference voltage circuit 203 as VERR. Then, a PWM comparator 210 outputs a result of comparing the output VERR of the air amplifier 208 with an output VOSC of a chopping wave oscillating circuit 209.

A switching circuit 212 outputs a pulse signal of a start-up oscillating circuit 211 to the EXT terminal through a buffer 213 until the output voltage VOUT becomes a regulated voltage. The pulse signal allows an external switch to switch, thereby setting up the output voltage. After the output voltage VOUT becomes the regulated voltage, the output of the PWM switching comparator 210 is switched and outputted to the EXT terminal.

With the above operation, the PWM switching regulator control circuit controls so that the output voltage VOUT becomes a desired voltage.

Also, there is disclosed a PWM control circuit in which a terminal for conducting a soft start at the time of start is lowered to the minimum value or lower of the VFB by the switching circuit to ignore the output voltage information at a secondary side at the time of an extremely reduced load, and operation is stably conducted while on-width control is not conducted (refer to JP 7-154965, FIG. 1 and pages 2 to 3)

However, in the above soft start, because a voltage at the non-inversion input terminal of the error amplifier 208 is 0 V at the time of start, the output VERR becomes 0 V. Conventionally, the output of the PWM comparator 210 becomes 0 V, and when the output voltage is stepped up and switched to the output of the PWM comparator 210 by the start-up oscillating circuit 211, an off-time during which a pulsed waveform is not outputted to the EXT terminal occurs.

Referring to FIG. 3, because the output waveform 302 of the error amplifier 208 starts from 0 V, the off-time occurs in the output waveform 304 of the PWM comparator 210. The voltage is not stepped up during the off-time, and the output voltage is lowered by means of a load, and a ripple voltage becomes large.

### SUMMARY OF THE INVENTION

An object of the present invention is to provide a PWM switching regulator control circuit which is small in the ripple voltage without a drop of the output voltage which is attributable to a load at the time of a soft start.

To attain the above object, a PWM switching regulator control circuit according to the present invention includes a second voltage dividing circuit including voltage dividing resistors that are connected in series and a switching element that is connected in series to the voltage dividing resistors, and a capacitor that is connected at an anode of the voltage dividing resistors, in which, when the switching element turns on at the time of turning on a power, the second voltage dividing circuit outputs an offset voltage that is lower than the reference voltage to the error amplifier.

Then, in the case where a feedback voltage becomes higher than an offset voltage, the switching element turns off to gradually step up the offset voltage. In addition, after the output voltage is sufficiently stepped up, the offset voltage becomes higher than the reference voltage.

Also, the resistance and the capacitor of the second voltage dividing circuit are varied, thereby enabling the offset voltage and the soft start time to be adjusted.

According to the PWM switching regulator control circuit of the present invention, when switching is made from the start-up oscillation to the PWM comparator output, it is possible to continue the step-up operation because the off-time does not occur in the PWM comparator output. Accordingly, it is possible to provide a PWM switching regulator control circuit that prevents the drop of the output voltage, which is attributable to the load and is small in a ripple voltage.

### BRIEF DESCRIPTION OF THE DRAWINGS

In the accompanying drawings:

FIG. 1 is a schematic diagram showing a PWM switching regulator control circuit in accordance with the present invention;

FIG. 2 is a schematic diagram showing a conventional PWM switching regulator control circuit; and

FIG. 3 is a timing chart showing the PWM switching regulator control circuit.

### DESCRIPTION OF THE PREFERRED EMBODIMENT

Hereinafter, a preferred embodiment of the present invention will be described in detail with reference to the drawings.

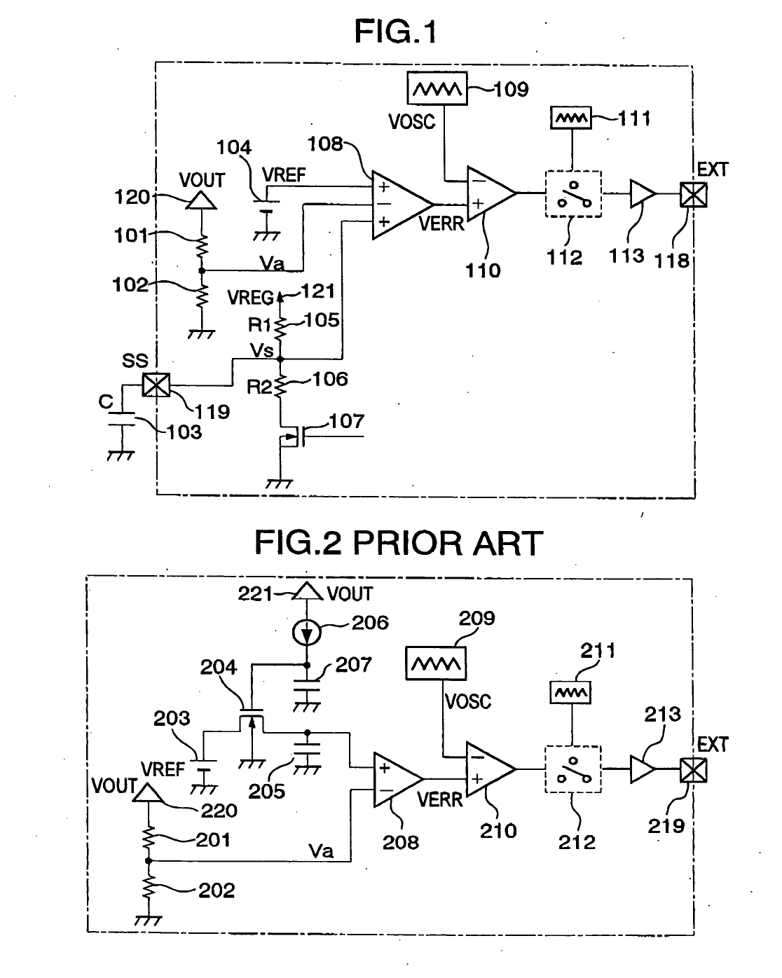

FIG. 1 is a schematic diagram showing a PWM switching regulator control circuit in accordance with the present invention.

The basic operation is identical with that of the conventional circuit except for the soft start. An error amplifier 108 outputs a difference between a feedback voltage Va derived from dividing an output voltage VOUT by division resistors 101 and 102, and a voltage VREF which is outputted from a reference voltage circuit 104 as VERR. Then, the PWM comparator 110 outputs a result of comparison between the output VERR of the error amplifier 108 and the output VOUT of the chopping wave oscillating circuit 109.

A switching circuit 112 outputs a pulse signal of a start-up oscillating circuit 111 to an EXT terminal until an output voltage VOSC becomes a regulated voltage. The pulse signal allows an external switch to switch over, thereby stepping up the output voltage VOUT. After the output voltage VOUT becomes the regulated voltage, the output voltage VOUT is switched to the output signal of the PWM comparator and then outputted to the EXT terminal.

With the above operation, the PWM switching regulator control circuit controls so that the output voltage VOUT becomes a desired voltage.

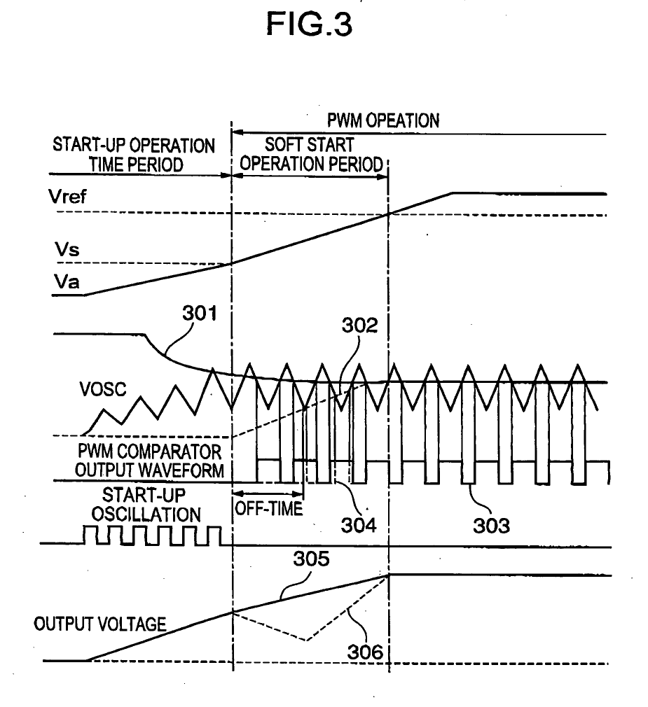

Now, the operation of the soft start function of the PWM switching regulator control circuit in accordance with the present invention will be described in order from a situation where no supply voltage is present at all with reference to FIGS. 2 and 3.

When a power supply is connected to the PWM switching regulator control circuit, an n-channel transistor 107 is on, a voltage Vs that has derived from dividing a regulator output voltage VREG that is supplied on the basis of a power supply by division resistors 105 and 106 is a given voltage value. The output voltage VOUT is stepped up by the pulse signal of the start-up oscillating circuit and gradually rises, and a feedback voltage Va that has been divided by the division resistors 101 and 102 in turn gradually rises. The error amplifier 108 outputs a difference between any lower voltage of the voltage Vs and the reference voltage VREF, and the feedback voltage Va as VERR. In this situation, since the voltage Vs is set to be lower than the reference voltage VREF, the error amplifier 108 outputs a difference between the voltage Vs and the feedback voltage va, which is gradually rising as VERR. Then; a period of time until the feedback voltage Va rises and exceeds the voltage Vs is a start-up operation period.

Then, when the feedback voltage Va exceeds the voltage Vs, the soft start operation period starts, and the switching circuit 112 switches to the output of the PWM comparator 110. At this time, the PWM comparator 110 outputs a result of the comparison between the output VERR of the error amplifier 108 and the output VOSC of the chopping wave oscillating circuit 209.

The n-channel transistor 107 turns off at the same time when the soft start is conducted, and the voltage Vs gradually rises up to VREG by the capacitor 103 that is connected to the division resistor 105 and an SS terminal 119. In this situation, the adjustment of the values of the division resistors 105, 106 and the capacitor 103 allows the offset voltage to be set to a desired value, thereby making it possible to step up the voltage Vs in accordance with a rising of the feedback voltage Vs.

In the above description, a period of time until the voltage Vs exceeds the reference voltage VREF is a soft start operation period, and thereafter the error amplifier 108 outputs a difference between the reference voltage VREF and the feedback voltage Va as VERR, which is the normal operation state.

As a result of the above operation, the voltage VERR is designated by reference numeral 301 in FIG. 3, and the output of the PWM comparator 110 is designated by reference numeral 303 in FIG. 3. Therefore, it is possible to eliminate the off-time of switching which is generated by the output 304 of the conventional PWM comparator 210, and it is possible to reduce the ripple of the output which is attributable to the load as indicated by reference numeral 306.

Note that the time of the soft start is determined in accordance with the capacitor 103 and the division resistors 105 and 106. Assuming that a capacitance of the capacity 103 is C, and a resistance of the resistor 105 is R1, a soft start time SS is represented by the following expression.
SS=C×R1 (3)
Also, the offset voltage VOFFSET is represented by the following expression.
VOFFSET=VREG×R2/(R1+R2) (4)
Through the expressions (3) and (4), the change of the capacitance of the capacitor 103 and the resistance makes it possible to adjust the soft start time and the offset voltage.

1. A PWM switching regulator control circuit having a soft start function, comprising:
a reference voltage source that generates a reference voltage;
a first voltage dividing circuit that divides an output voltage to output a feedback voltage;
an error amplifier that outputs a difference between the reference voltage and the feedback voltage;
a chopping wave oscillating circuit that outputs a chopping wave;
a PWM comparator that compares the output of the error amplifier and the chopping wave to output a pulse signal;
a start-up circuit that outputs the pulse signal;
a switching circuit that switches between the pulse signal of the PWM comparator and the pulse signal of the start-up circuit to output the switched pulse signal to an EXT terminal;
a second voltage dividing circuit including voltage dividing resistors that are connected in series and a switching element that is connected in series to the voltage dividing resistors; and
a capacitor that is connected to a connecting point of the voltage dividing resistors of the second voltage dividing circuit,
wherein when the switching element turns on at the time of turning on a power, the second voltage dividing circuit outputs an offset voltage that is lower than the reference voltage to the error amplifier, and a pulse signal is outputted to the EXT terminal even at the time of a soft start to enable a voltage boosting operation.

2. A PWM switching regulator control circuit according to claim 1, wherein the offset voltage is stepped up with a rising of the feedback voltage when the switching element turns off.

3. A PWM switching regulator control circuit according to claim 1, wherein a resistance of the second voltage dividing circuit is adjusted to make the offset voltage variable.

4. A PWM switching regulator control circuit according to claim 1, wherein a capacitance of the capacitor is adjusted to make a time of the soft start variable.
